(19) United States
(12) Patent Application Publication
(10) Pub. No.: US 2014/0016239 A1
(43) Pub. Date: Jan. 16, 2014

(54) THRESHOLD VOLTAGE AND DELAY TIME SETTING CIRCUIT, AND BATTERY MANAGEMENT SYSTEM INCLUDING THE SAME

(71) Applicant: FAIRCHILD KOREA SEMICONDUCTOR LTD., Kyungki-do (KR)

(72) Inventors: Jin-Tae KIM, Seoul (KR); Eun CHEON, Seoul (KR)

(21) Appl. No.: 13/941,927

(22) Filed: Jul. 15, 2013

(30) Foreign Application Priority Data
Jul. 16, 2012 (KR) 10-2012-0077416

(51) Int. Cl. H02H 11/00; H03K 21/02

(52) U.S. Cl. CPC H02H 11/007; H03K 21/023
USPC 361/92; 327/279

(57) ABSTRACT

The present invention relates to a threshold voltage and delay time setting circuit, and a battery management system including the same. The setting circuit is connected to a set resistor and a set capacitor through a pin. The setting circuit includes a threshold voltage setter for setting a threshold voltage according to resistance of the set resistor, and a delay setter for determining a count frequency according to capacitance of the set capacitor and setting a delay time according to the determined count frequency.

### CROSS-REFERENCE TO RELATED APPLICATION

This application claims priority to and the benefit of Korean Patent Application No. 10-2012-0077416 filed in the Korean Intellectual Property Office on Jul. 16, 2012, the entire contents of which are incorporated herein by reference.

### BACKGROUND OF THE INVENTION

(a) Field of the Invention

The present invention relates to a circuit for setting a threshold voltage and a delay time for controlling a protection operation. Particularly, the present invention relates to a battery management system including a circuit for setting a reference voltage and a delay time.

(b) Description of the Related Art

A battery management system controls various protection operations to prevent damage to the battery. An overvoltage and overcurrent that may occur when the battery is charged and a low voltage when the battery is discharged represent factors for degrading the battery.

Various threshold voltages for sensing the degradation factors must be set for the battery management system. Also, there is a predetermined delay time between a time when the degradation factors are sensed and a time when a protection operation is performed so as to prevent the protection operation from being performed by the degradation causes that are instantly generated. A delay time must also be set for the battery management system.

However, the conventional battery management system requires at least two pins for the respective protection operations in order to set various threshold voltages and the delay time for the battery management system. Also, the battery management system can include a memory such as an EEPROM in order to store information on the predetermined threshold voltage and the delay time.

The usage of the expensive EEPROM may be a cause to increase the production cost of the battery management system, and it can also become a factor for increasing a size of the battery management system. In addition, when the number of pins for the battery management system is increased, the battery management system becomes bigger.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a setting circuit for using a lesser number of pins to set a threshold voltage and a delay time and having no memory for storing the threshold voltage and the delay time, and a battery management system including the same.

An exemplary embodiment of the present invention provides a setting circuit connected to a set resistor and a set capacitor through a pin, including: a threshold voltage setter for setting a threshold voltage according to resistance of the set resistor; and a delay setter for determining a count frequency according to capacitance of the set capacitor and setting a delay time according to the determined count frequency.

The threshold voltage setter supplies a set current to the set resistor and uses a dependent current following the set current to set a threshold voltage so as to control a voltage that is generated in the set resistor with a predetermined set reference voltage.

The threshold voltage setter sums currents of a plurality of selected sink current sources from among a plurality of sink current sources to generate a summed sink current according to a result of comparing a set voltage generated by the dependent current and a plurality of reference voltages, and sets the threshold voltage according to the summed sink current.

The threshold voltage setter includes: a plurality of voltage comparators including a first input terminal for receiving the set voltage and a second input terminal for receiving a corresponding reference voltage from among the plurality of reference voltages; a plurality of SR latches for writing and maintaining outputs of the voltage comparators, and generating a plurality of output signals according to the outputs of the comparators; and a threshold voltage generator for selecting the sink current sources according to output signals of the SR latches and generating the summed sink current.

The threshold voltage generator includes: a plurality of sink switches connected between first ends of the sink current sources and a ground; a first current mirror circuit including an input terminal connected to second ends of the sink current sources, mirroring the summed sink current sunk to the input terminal, and outputting the same to an output terminal; and an output resistor connected to the output terminal of the first current mirror circuit, wherein the sink switches are respectively switched according to a corresponding output signal from among a plurality of output signals of the plurality of SR latches, and the threshold voltage is generated at the output resistor.

The threshold voltage setter determines resistance of a resistor string according to a result of comparing a set voltage generated by the dependent current and a plurality of reference voltages and sets the threshold voltage according to the determined resistance.

The threshold voltage setter includes: a plurality of voltage comparators including a first input terminal for receiving the set voltage and a second input terminal for receiving a corresponding reference voltage from among the plurality of reference voltages; a plurality of SR latches for writing and maintaining outputs of the plurality of voltage comparators, and generating a plurality of output signals according to outputs of the respective voltage comparators; and a threshold voltage generator for determining resistance of the resistor string according to a plurality of output signals of the SR latches, and generating the threshold voltage according to the determined resistance.

The threshold voltage setter includes: a plurality of resistor switches connected in parallel to a plurality of resistors configuring the resistor string; and a first resistor connected between the resistor string and the reference voltage, wherein the resistor switches are respectively switched according to a corresponding output signal from among the output signals of the SR latches, and the threshold voltage is generated between the first resistor and the reference voltage.

The threshold voltage setter generates a summed sink current by summing currents of a plurality of selected sink current sources from among a plurality of sink current sources according to a result of comparing the dependent current and a plurality of reference currents, and sets the threshold voltage according to the summed sink current.

The threshold voltage setter includes: a second current mirror circuit for generating a mirror current by mirroring the dependent current; a plurality of current comparators including a first input terminal for receiving the mirror current and a second input terminal for receiving a corresponding reference current from among the plurality of reference currents; a plurality of SR latches for writing and maintaining outputs of the current comparators, and generating a plurality of output signals according to outputs of the current comparators; and a threshold voltage generator for generating the summed sink current by selecting the sink current sources according to the output signals of the SR latches.

The threshold voltage generator includes: a plurality of sink switches connected between first ends of the sink current sources and a ground; a first current mirror circuit including an input terminal connected to the second ends of the sink current sources, mirroring the summed sink current sunk to the input terminal, and outputting the same to an output terminal; and an output resistor connected to the output terminal of the first current mirror circuit, wherein the sink switches are switched according to a corresponding output signal from among a plurality of output signals of the SR latches, and the threshold voltage is generated at the output resistor.

The threshold voltage setter determines resistance of the resistor string according to a result of comparing the dependent current and a plurality of reference currents, and sets the threshold voltage according to the determined resistance.

The threshold voltage setter includes: a second current mirror circuit for generating a mirror current by mirroring the dependent current; a plurality of current comparators including a first input terminal for receiving the mirror current and a second input terminal for receiving a corresponding reference current from among the reference currents; a plurality of SR latches for writing and maintaining outputs of the current comparators, and generating a plurality of output signals according to outputs of the current comparators; and a threshold voltage generator for determining resistance of the resistor string according to a plurality of output signals of the SR latches, and generating the threshold voltage according to the determined resistance.

The threshold voltage setter includes: a plurality of resistor switches connected in parallel to a plurality of resistors configuring the resistor string; and a first resistor connected between the resistor string and a reference voltage, wherein the resistor switches are switched according to a corresponding output signal from among a plurality of output signals of the SR latches, and the threshold voltage is generated between the first resistor and the reference voltage.

The threshold voltage setter further includes: an error amplifier for amplifying a difference between the set reference voltage and a voltage at the set resistor, and outputting the amplified voltage difference; and a BJT operable by an output of the error amplifier, wherein the set current flows through the BJT.

The threshold voltage setter further includes: a voltage-current converter for generating the dependent current according to a sense voltage that is generated when the set current flows through a resistor; and an RC filter including a resistor through which the dependent current flows and a capacitor connected in parallel to the resistor, wherein a voltage flowing through the resistor is the set voltage.

The delay setter charges the set capacitor to increase a voltage at the pin, discharges the set capacitor to reduce the voltage at the pin, and sets the delay time when a result of counting count pulses that are generated when the voltage at the pin is increased or reduced reaches a predetermined number of threshold times.

The delay setter includes: a charge and discharge controller for charging and discharging the set capacitor according to the count pulse; a comparator comparing a first result generated by comparing the voltage at the pin and a predetermined high reference voltage and a second result generated by comparing the voltage at the pin and a predetermined low reference voltage; an SR latch for controlling the charging according to the first result and controlling discharging according to the second result; an AND gate for generating the count pulse according to an output of the SR latch; and a counter for counting a period of the count pulse, and generating a protection signal when the count result reaches the number of threshold times.

The charge and discharge controller includes a current source for generating a charge current; and a charge and discharge control switch connected between the current source and the pin, and switched according to the count pulse.

A period in which the threshold voltage setter is connected to the pin is not overlapped over a period in which the delay setter is connected to the pin.

Another embodiment of the present invention provides a system for managing a battery having a plurality of cells including: a control circuit connected to the cells, sensing cell voltages of the respective cells and a current flowing through the battery, generating a detection signal according to a result of comparing the cell voltages and at least one threshold voltage, and performing a protecting operation according to at least one protection signal; and a setting circuit for setting the at least one threshold voltage, setting a delay time from a time when the detection signal is generated to a time when the protecting operation is performed, and generating the at least one protection signal wherein the setting circuit follows the above-described setting circuit.

The threshold voltage setter is performed during an initialization interval and a register writing interval of the battery management system, and the delay setter is performed when the detection signal is generated after the initialization interval and the register writing interval are finished.

According to the embodiments of the present invention, a setting circuit for using a less number of pins to set a threshold voltage and a delay time and having no memory for storing the threshold voltage and the delay time, and a battery management system including the same are provided.

### BRIEF DESCRIPTION OF THE DRAWINGS

FIG. 1 shows a block diagram of a battery management system including a setting circuit according to an exemplary embodiment of the present invention.

FIG. 2 shows an OV threshold voltage setter according to an exemplary embodiment of the present invention.

FIG. 3 shows an OV delay setter according to an exemplary embodiment of the present invention.

FIG. 4 shows a threshold voltage generator according to another exemplary embodiment of the present invention.

FIG. 5 shows an OV threshold voltage setter according to the other exemplary embodiment of the present invention.

FIG. 6 shows an OV threshold voltage setter according to the other exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout this specification and the claims that follow, when it is described that an element is “coupled” to another element, the element may be “directly coupled” to the other element or “electrically coupled” to the other element through a third element. In addition, unless explicitly described to the contrary, the word “comprise” and variations such as “comprises” or “comprising” will be understood to imply the inclusion of stated elements but not the exclusion of any other elements.

Exemplary embodiments of the present invention will now be described with reference to accompanying drawings.

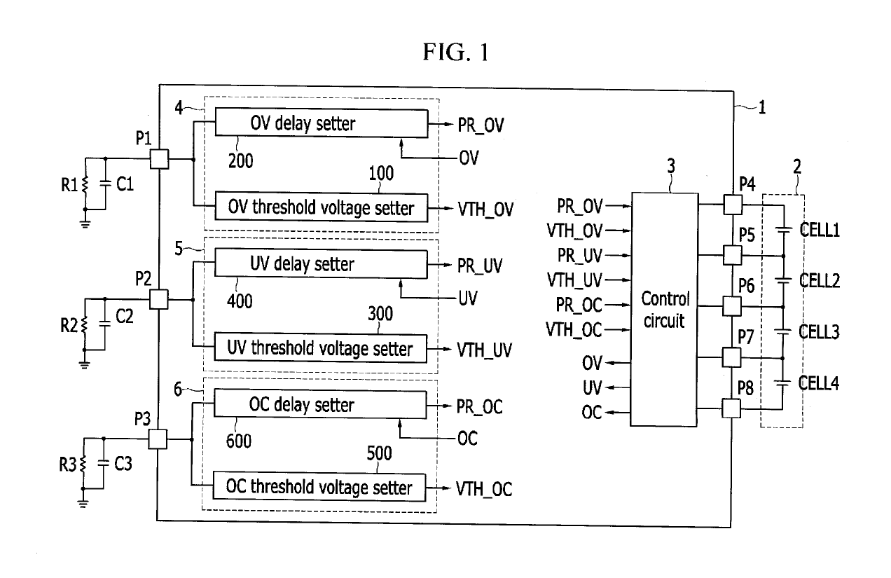

FIG. 1 shows a block diagram of a battery management system including a setting circuit according to an exemplary embodiment of the present invention.

As shown in FIG. 1, the battery management system 1 is connected to a battery 2 and includes a plurality of setting circuits 4, 5, and 6.

The battery 2 includes a plurality of cells (CELL1-CELL4) that are connected in series. FIG. 1 exemplarily shows four cells, which is given for ease of description, and the number of cells depends on the rated output of the battery 2.

The control circuit 3 is connected to both ends of the cells (CELL1-CELL4) through five pins (P4-P8), measures voltages of the cells (CELL1-CELL4) to prevent overcharge and overdischarge, controls cell balancing among the plurality of cells, and measures a charge and discharge current of the battery 2 to control the charge and discharge current.

For example, the control circuit 3 compares the voltages of the cells (CELL1-CELL4) (hereinafter, cell voltages) with an overvoltage threshold voltage (VTH_OV), and generates an overvoltage detection signal (OV) when a voltage that is greater than the overvoltage threshold voltage (VTH_OV) is found from among a plurality of cell voltages.

The control circuit 3 compares the plurality of cell voltages and a low voltage threshold voltage, and generates a low voltage detection signal (UV) when a voltage that is less than the low voltage threshold voltage (VTH_UV) is found from among the plurality of cell voltages.

The control circuit 3 measures a charge and discharge current of the sensed battery 2 to generate a measured voltage, compares the measured voltage and an overcurrent threshold voltage (VTH_OC), and generates an overcurrent detection signal (OC) when the measured voltage is greater than the overcurrent threshold voltage (VTH_OC).

The control circuit 3 receives an overvoltage protecting signal (PR_OV) from the overvoltage setting circuit 4, a low voltage protecting signal (PR_UV) from the low voltage setting circuit 5, and an overcurrent protecting signal (PR_OC) from the overcurrent setting circuit 6, and performs the protection operation by the signals.

The overvoltage setting circuit 4 sets an overvoltage threshold voltage (VR_OV) for determining whether a voltage to be sensed is an overvoltage, and sets a delay time (hereinafter, overvoltage delay time) from the time when the overvoltage is sensed to the time when the overvoltage protecting operation begins. The overvoltage setting circuit 4 is connected to a set resistor R1 and a set capacitor C1 through a pin P1.

For example, the overvoltage protecting operation signifies an operation for protecting the battery 2 from the overvoltage state that may occur while the battery 2 is being charged. Therefore, the voltage to be sensed represents each voltage (hereinafter, cell voltage) of the plurality of cells (CELL1-CELL4) of the battery 2.

The control circuit 3 determines an overvoltage state according to a result of comparing the overvoltage threshold voltage (VTH_OV) set by the overvoltage setting circuit 4 and the cell voltage, and generates an enable-level overvoltage detection signal (OV).

The overvoltage detection signal (OV) is transmitted to the overvoltage setting circuit 4, and the overvoltage setting circuit 4 sets an overvoltage delay time starting from the time when the enable-level overvoltage detection signal (OV) is generated. The overvoltage setting circuit 4 sets the overvoltage delay time when the counting result according to a count frequency reaches a predetermined value (hereinafter, overvoltage count). The overvoltage setting circuit 4 generates an overvoltage protecting signal (PR_OV) when the setting of the overvoltage delay time is finished. The overvoltage protecting signal (PR_OV) is transmitted to the control circuit 3, and the control circuit 3 can stop the charging operation according to the overvoltage protecting signal (PR_OV).

The overvoltage setting circuit 4 includes an OV threshold voltage setter 100 for setting the overvoltage threshold voltage (VTH_OV) and an OV delay setter 200 for setting the overvoltage delay time.

The OV threshold voltage setter 100 sets the overvoltage threshold voltage (VTH_OV) according to resistance of the set resistor R1. Therefore, the overvoltage threshold voltage (VTH_OV) can be controlled by controlling the set resistor R1. The OV delay setter 200 determines a count frequency according to capacitance of the set capacitor C1. Therefore, the overvoltage delay time can be controlled by controlling capacitance of the set capacitor C1.

Accordingly, a user can set the overvoltage delay time to be a desired one by controlling capacitance of the set capacitor C1, and he can set the desired set overvoltage threshold voltage (VTH_OV) by controlling resistance of the resistor R1.

The low voltage setting circuit 5 sets a low voltage threshold voltage (VR_UV) for determining whether a voltage to be sensed is a low voltage and a delay time (hereinafter, low voltage delay time) from the time when the low voltage is sensed to the time when a low voltage protecting operation begins. The low voltage setting circuit 5 is connected to a set resistor R2 and a set capacitor C2 through a pin P2.

For example, the low voltage protecting operation represents an operation for protecting the battery 2 from the low voltage that may occur when the battery 2 is discharged. Therefore, the voltage to be sensed includes a plurality of cell voltages.

The control circuit 3 determines a low voltage state according to a result of comparing the low voltage threshold voltage (VTH_UV) set by the low voltage setting circuit 5 and the cell voltage and generates an enable-level low voltage detection signal (UV).

The low voltage detection signal (UV) is transmitted to the low voltage setting circuit 5, and the low voltage setting circuit 5 sets the low voltage delay time when the enable-level low voltage detection signal (UV) is generated. The low voltage setting circuit 5 sets the low voltage delay time when the counting result based on the count frequency reaches a predetermined value (hereinafter, low voltage count).

The low voltage setting circuit 5 generates a low voltage protecting signal (PR_UV) for performing the protection operation when the setting of the low voltage delay time is finished. The low voltage protecting signal (PR_UV) is transmitted to the control circuit 3, and the control circuit 3 can stop the discharge operation according to the low voltage protecting signal (PR_UV).

The low voltage setting circuit 5 includes a UV threshold voltage setter 300 for setting the low voltage threshold voltage (VTH_UV) and a UV delay setter 400 for setting the low voltage delay time.

The UV threshold voltage setter 300 sets the low voltage threshold voltage (VTH_UV) according to resistance of the set resistor R2. Therefore, the low voltage threshold voltage (VTH_UV) can be controlled by controlling the set resistor R2. The UV delay setter 400 determines the count frequency according to capacitance of the set capacitor C2. Therefore, the low voltage delay time can be controlled by controlling capacitance of the set capacitor C2.

Accordingly, the user can set the low voltage delay time to be a desired one by controlling capacitance of the set capacitor C2, and can set a desired low voltage threshold voltage (VTH_UV) by controlling resistance of the set resistor R2.

The overcurrent setting circuit 6 sets the overcurrent threshold voltage (VR_OC) for determining whether the current to be sensed is an overcurrent, and it sets a delay time (hereinafter, overcurrent delay time) from the time when the overcurrent is sensed to the time when the overcurrent protecting operation begins. The overcurrent setting circuit 6 is connected to the set resistor R3 and the set capacitor C3 through the pin P3.

For example, the overcurrent protecting operation is an operation for protecting the battery 2 from the state in which the charge and discharge current of the battery 2 is excessively high. Therefore, the current to be sensed represents the charge and discharge current of the battery 2.

The control circuit 3 determines the overcurrent state according to a result of comparing the overcurrent threshold voltage (VTH_OC) set by the overcurrent setting circuit 6 and the voltage generated when the charge and discharge current of the battery 2 is sensed, and generates an enable-level overcurrent detection signal (OC).

The overcurrent detection signal (UV) is transmitted to the overcurrent setting circuit 6, and the overcurrent setting circuit 6 sets the overcurrent delay time when the enable-level overcurrent detection signal (OC) is generated. The overcurrent setting circuit 6 sets the overcurrent delay time when the counting result based on the count frequency reaches a predetermined value (hereinafter, overcurrent count).

The overcurrent setting circuit 6 generates an overcurrent protecting signal (PR_OC) for performing the protection operation when the setting of the overcurrent delay time is finished. The overcurrent protecting signal (PR_OC) is transmitted to the control circuit 3, and the control circuit 3 can stop the charge and discharge operation according to the overcurrent protecting signal (PR_OC).

The overcurrent setting circuit 6 includes an OC threshold voltage setter 500 for setting the overcurrent threshold voltage (VTH_OC) and an OC delay setter 600 for setting the overcurrent delay time.

The OC threshold voltage setter 500 sets the overcurrent threshold voltage (VTH_OC) according to resistance of the set resistor R3. Therefore, the overcurrent threshold voltage (VTH_OC) can be controlled by controlling the set resistor R3. The OC delay setter 600 determines the count frequency according to capacitance of the set capacitor C3. Hence, the overcurrent delay time can be controlled by controlling capacitance of the set capacitor C3.

As described, the user set the overcurrent delay time as desired by controlling capacitance of the set capacitor C3, and can set a desired overcurrent threshold voltage (VTH_OC) by controlling resistance of the set resistor R3.

The above-described overvoltage, the low voltage, and the overcurrent protection operation are examples from among various protection operations, and the battery management system according to the exemplary embodiment of the present invention can set a reference voltage and a delay time for controlling an additional protection operation.

When the reference voltage and the delay time are set by using the setting circuit according to the exemplary embodiment of the present invention, the battery management system needs to include a pin that is connected to the set resistor and the set capacitor. Further, since the reference voltage is controlled by the set resistor and the delay time is controlled by the set capacitor, there is no need to use a big and expensive memory, such as an EEPROM, for storing the reference voltage and the delay time.

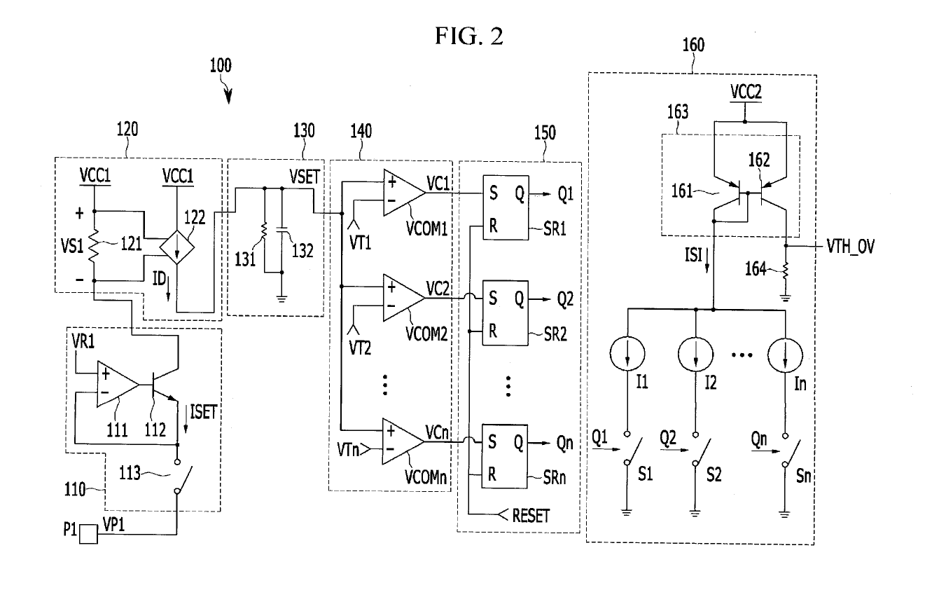

An OV threshold voltage setter will now be described with reference to FIG. 2. The configuration and operation of the OC threshold voltage setter and the UV threshold voltage setter correspond to those of the OV threshold voltage setter so no repeated detailed description on the OC threshold voltage setter and the UV threshold voltage setter will be provided.

FIG. 2 shows an OV threshold voltage setter according to an exemplary embodiment of the present invention.

As shown in FIG. 2, the OV threshold voltage setter 100 includes a current generator 110, a voltage-current converter 120, an RC filter 130, a comparator 140, a register 150, and a threshold voltage generator 160. The current generator 110 generates a set current (ISET) so that the voltage of the set resistor R1 may be a predetermined set reference voltage (VR1). The current generator 110 includes an error amplifier 111, an n-channel type BJT 112, and a switch 113.

The switch 113 is turned on during an initialization interval and a register writing interval. During the initialization interval, a power voltage for operating the overvoltage setting circuit 4 reaches a normal level, and during the register writing interval, the overvoltage threshold voltage (VTH_OV) is set by information written in the register 150.

The error amplifier 111 includes a non-inverting terminal (+) for receiving a reference voltage VR1 and an inverting terminal (−) connected to the pin 1, and an output end of the error amplifier 111 is connected to a base of the BJT 112.

The error amplifier 111 amplifies a difference between the voltage at the non-inverting terminal (+) and the voltage at the inverting terminal (−), and outputs the amplified voltage. That is, the error amplifier 111 amplifies the difference between the reference voltage VR1 and the voltage VP1 at the pin 1 to control the set current (ISET) flowing through the BJT 112. The voltage VP1 at the pin 1 is the product of the set current (ISET) and the set resistor R1.

For example, when the voltage VP1 at the pin 1 is reduced, an output of the error amplifier 111 is increased to increase the set current (ISET) flowing through the BJT 112 and increase the voltage VP1 at the pin 1. When the voltage VP1 at the pin 1 is increased, the output of the error amplifier 111 is reduced to reduce the set current (ISET) and reduce the voltage VP1 at the pin 1.

Hence, the voltage VP1 at the pin 1 includes a ripple with respect to the reference voltage VR1 and it is maintained at the reference voltage VR1. The ripple is a very much smaller value than the reference voltage VR1 and it is ignorable. Therefore, the set current (ISET) is maintained at a constant.

The voltage-current converter 120 converts the sense voltage VS1 generated by the set current (ISET) into a current and transmits it to the comparator 140. The voltage-current converter 120 includes a sense resistor 121 and a dependent current source 122.

The sense resistor 121 is connected between the voltage source VCC1 and the BJT 112, and the sense voltage VS1 that is generated when the set current (ISET) flows through the sense resistor 121 is transmitted to the dependent current source 122.

The dependent current source 122 is connected to the voltage source VCC1, and it uses the voltage of the voltage source VCC1 to generate a dependent current (ID) following the sense voltage VS1.

The RC filter 130 includes a resistor 131 and a capacitor 132 connected in parallel to the resistor 131. The RC filter 130 generates a set voltage (VSET) by filtering a voltage that is generated when the dependent current (ID) flows through the resistor 131 of the RC filter 130.

The comparator 140 generates a plurality of voltage comparing signals (VC1-VCn) according to a result of comparing a plurality of reference voltages (VT1-VTn) and the set voltage (VSET). The comparator 140 includes a plurality of voltage comparators (VCOM1-VCOMn).

The voltage comparators (VCOM1-VCOMn) respectively include a non-inverting terminal (+) for receiving the set voltage (VSET) and an inverting terminal (−) for receiving a corresponding reference voltage from among the plurality of reference voltages (VT1-VTn), and generate a plurality of voltage comparing signals (VC1-VCn) according to a comparison result.

The voltage comparators (VCOM1-VCOMn) respectively output a high level signal when an input of the non-inverting terminal (+) is greater than an input of the inverting terminal (−), and it output a low level signal. Therefore, the number of high-level voltage comparing signals from among the plurality of voltage comparing signals (VC1-VCn) depends on the set voltage (VSET).

For example, as the set voltage (VSET) becomes greater, the number of the high-level voltages comparing signals is increased from among the plurality of voltage comparing signals (VC1-VCn).

The voltage comparing signals (VC1-VCn) are respectively transmitted to a set terminal (S) of the corresponding SR latch from among a plurality of SR latches (SR1-SRn) included in the register 150.

The register 150 writes and stores a plurality of voltage comparing signals (VC1-VCn) and generates a plurality of output signals (Q1-Qn) corresponding to the voltage comparing signals (VC1-VCn). The register 150 includes a plurality of SR latches (SR1-SRn).

The SR latches (SR1-SRn) respectively include a set terminal (S) for receiving a corresponding voltage comparing signal from among the plurality of voltage comparing signals (VC1-VCn) and a reset terminal (R) for receiving the reset signal (RESET), and generate a high-level output signal when an input to the set terminal (S) is high-level, maintain the current output when the input to the set terminal (S) is low-level, and reset the output when the input to the reset terminal (R) is high-level.

The reset signal (RESET) becomes a high-level pulse before an overvoltage threshold voltage is reset. For example, during the initialization interval, the reset signal (RESET) becomes a high-level pulse to reset the output signals (Q1-Qn) of the register 150 to be low-level signals.

During the register writing interval (the reset signal (RESET) is low-level) after the initialization interval, a plurality of SR latches (SR1-SRn) determine and maintain the output according to the input of the set terminal (S).

The threshold voltage generator 160 generates an overvoltage threshold voltage (VTH_OV) according to a sink current controllable by the output signals (Q1-Qn) of the register 150. The threshold voltage generator 160 includes a plurality of sink current sources (I1-In), a plurality of sink switches (S1-Sn), a first current mirror circuit 163, and an output resistor 164.

A corresponding sink switch from among a plurality of sink switches (S1-Sn) is connected between respective sink current sources (I1-In) and ground. The sink switches (S1-Sn) are respectively switched according to a corresponding output signal from among the output signals (Q1-Qn).

For example, the sink switch (Si) is turned on by the high-level output signal (Qi), and it is turned off by the low-level output signal (Qi). When i is a random integer from among the integers 1 to n, the sink current of a plurality of sink current sources (I1-In) flows when the corresponding sink switch is turned on.

The first current mirror circuit 163 is operated by the voltage of the voltage source VCC2, is connected to the sink current sources (I1-In), and mirrors a sum (ISI) of sink currents of the sink current sources (I1-In) (hereinafter, summed sink current). The first current mirror circuit 163 includes a BJT 161 and a BJT 162, and in the first current mirror circuit 163, a terminal at which the summed sink current (ISI) is sunk is called an input terminal and a terminal for outputting the mirrored current is called an output terminal.

A collector of the BJT 161 is connected to a voltage source VCC2, and a base thereof is connected to an emitter thereof. The emitter of the BJT 161 is connected to the sink current sources (I1-In). A collector of the BJT 162 is connected to the voltage source VCC2, and the base of the BJT 161 is connected to a base of the BJT 162. The summed sink current (ISI) flowing through the BJT 161 is mirrored to flow through the BJT 162.

The output resistor 164 is connected between an output terminal (the emitter of the BJT 162) of the first current mirror circuit 163 and the ground, and the voltage generated at the output resistor 164 is the overvoltage threshold voltage (VTH_OV).

For example, the set voltage (VSET) will be assumed to be greater than a plurality of reference voltages (VTm-VTn) from among a plurality of reference voltages (VT1-VTn). When it is given as 1<m<n, a plurality of voltage comparing signals (VCm-VCn) are high-level from among a plurality of voltage comparing signals (VC1-VCn), and a plurality of output signals (Qm-Qn) are high-level.

A plurality of sink switches (Sm-Sn) are then turned on, and the summed sink current (ISI) is the sum of sink currents of a plurality of sink current sources (Im-In). The summed sink current (ISI) is mirrored to flow through the output resistor 164 and generate an overvoltage threshold voltage (VTH_OV).

In this instance, when the generated overvoltage threshold voltage (VTH_OV) is less than a desired condition, the set resistor R1 is reduced, and in another case, the set resistor R1 is increased.

When the set resistor R1 is reduced, the set current (ISET) for maintaining the voltage VP1 at the pin 1 as a set reference voltage VR1 is increased and the set voltage (VSET) is also increased. The number of high-level output signals from among a plurality of output signals (Q1-Qn) is increased and the number of turned on switches from among a plurality of sink switches (S1-Sn) is increased. Therefore, the summed sink current (ISI) is increased and the overvoltage threshold voltage (VTH_OV) is increased.

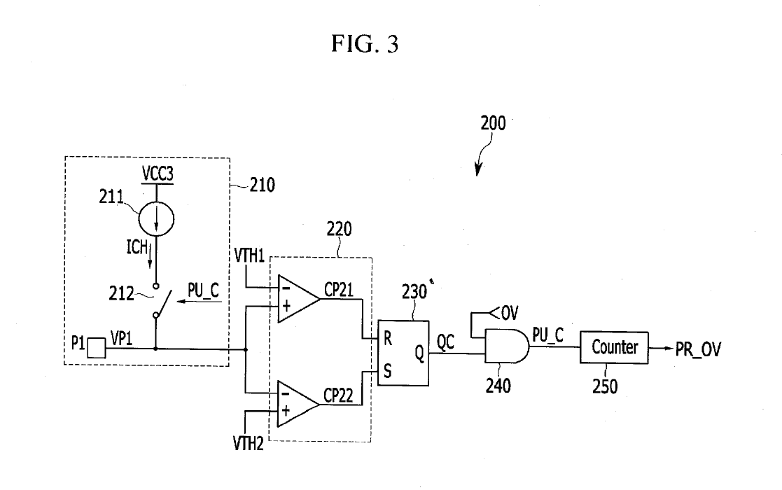

An OV delay setter 200 according to an exemplary embodiment of the present invention will now be described with reference to FIG. 3. When the initialization interval and the register writing interval are finished and an abnormal state such as overvoltage, a low voltage, or an overcurrent is generated while the battery management system is operated, the delay setter is operated. Therefore, the period in which the OV threshold voltage setter 100 is connected to the pin 1 is not overlapped with the period in which the OV delay setter 200 is connected to the pin 1.

FIG. 3 shows an OV delay setter according to an exemplary embodiment of the present invention.

As shown in FIG. 3, the OV delay setter 200 includes a charge and discharge controller 210, a comparator 220, an SR latch 230, an AND gate 240, and a counter 250. An overvoltage detection signal (OV) according to an exemplary embodiment of the present invention is set to be high-level in the case of an overvoltage state.

The charge and discharge controller 210 includes a current source 211 and a charge and discharge control switch 212. The current source 211 uses a voltage of a voltage source VCC3 to generate a charge current (ICH). The charge and discharge control switch 212 is switched according to a count pulse (PU_C) when an overvoltage is sensed.

While the charge and discharge control switch 212 is turned on, the set capacitor C1 is charged by the charge current (ICH) and the voltage VP1 at the pin 1 is increased. While the charge and discharge control switch 212 is turned off, the set capacitor C1 is discharged and the voltage VP1 at the pin 1 is reduced.

The comparator 220 compares the voltage VP1 at the pin 1, a high reference voltage VTH1, and a low reference voltage VTH2. The comparator 220 includes a first comparator 221 and a second comparator 222. The first comparator 221 generates a comparing signal CP21 according to a result of comparing the high reference voltage VTH1 and the voltage VP1 at the pin 1. The first comparator 221 includes a non-inverting terminal (+) for receiving the voltage VP1 and an inverting terminal (−) for receiving the high reference voltage VTH1.

The second comparator 222 generates a comparing signal CP22 according to a result of comparing the low reference voltage VTH2 and the voltage VP1 of the pin 1. The second comparator 222 includes an inverting terminal (−) for receiving the voltage VP1 and a non-inverting terminal (+) for receiving the low reference voltage VTH2.

The first comparator 221 and the second comparator 222 output high-level signals when the input of the non-inverting terminal (+) is greater than the input of the inverting terminal (−), and they output low-level signals in another case.

The SR latch 230 includes a reset terminal (R) for receiving the comparing signal CP21 and a set terminal (S) for receiving the comparing signal CP22, generates a high-level output signal (QC) when the input of the set terminal (S) is high-level, and generates a low-level output signal (QC) when the input of the reset terminal (R) is high-level.

The AND gate 240 performs an AND operation on the overvoltage detection signal (OV) and the output signal (QC) to generate a count pulse (PU_C).

The counter 250 counts the count pulse (PU_C), and when the count result reaches a predetermined number of threshold times, it generates an enable-level overvoltage protecting signal (PR_OV). The control circuit 3 stops the charge operation for inputting the enable-level overvoltage protecting signal (PR_OV).

For example, when the overvoltage detection signal (OV) becomes high-level (i.e., an overvoltage is generated), two inputs to the AND gate 240 become high-level and the count pulse (PU_C) becomes high-level. When the initialization interval and the register writing interval are finished, the pin 1 floats and the voltage VP1 is the zero voltage. Therefore, the comparing signal CP22 is high-level and the output signal (QC) of the SR latch 230 is high-level. In this state, when a high-level overvoltage detection signal (OV) is generated, the count pulse (PU_C) becomes high-level.

The charge and discharge control switch 212 is turned on, the set capacitor C1 is charged, and the voltage VP1 is increased. When the increasing voltage VP1 reaches the high reference voltage VTH1, the comparing signal CP21 becomes high-level, the output signal (QC) becomes low-level, and the count pulse (PU_C) becomes low-level. The charge and discharge control switch 212 is turned off.

When the charge and discharge control switch 212 is turned off, the set capacitor C1 is discharged and the voltage VP1 is reduced. When the reducing voltage VP1 reaches the low reference voltage VTH1, the comparing signal CP22 becomes high-level, the output signal (QC) becomes high-level, and the count pulse (PU_C) becomes high-level. The charge and discharge control switch 212 is turned on. The voltage VP1 is increased again.

When the above-noted operation is repeated, the count pulse (PU_C) with a constant frequency is generated. The count frequency represents the frequency of the count pulse (PU_C). Rising of the voltage VP1 and an increase slope are controlled by capacitance of the set capacitor C1 so the frequency of the count pulse (PU_C) is controlled.

The count 250 counts the period of the count pulse (PU_C) (e.g., rising edge), and when the count result reaches a threshold number of times, it outputs a high-level overvoltage protecting signal (PR_OV).

Also, when the protection operation is performed by the high-level overvoltage protecting signal (PR_OV), the overvoltage detection signal (OV) is reset and the count pulse (PU_C) becomes low-level. The charge and discharge control switch 212 is maintained at the turn-off state, and the voltage VP1 becomes the zero voltage.

The configuration and the operation of the OV threshold voltage setter 100 and OV delay setter 200 that are described with reference to FIG. 2 and FIG. 3 are applicable to the UV threshold voltage setter 300 and the UV delay setter 400. However, the overvoltage detection signal (OV) is replaced with the low voltage detection signal (UV), the overvoltage protecting signal (PR_OV) is replaced with the low voltage protecting signal (PR_UV), and the overvoltage threshold voltage (VTH_OV) is replaced with the low voltage threshold voltage (VTH_UV).

In a like manner, the configuration and the operation of the OV threshold voltage setter 100 and the OV delay setter 200 are applicable to the OC threshold voltage setter 500 and the OC delay setter 600. However, the overvoltage detection signal (OV) is replaced with the overcurrent detection signal (OC), the overvoltage protecting signal (PR_OV) is replaced with the overcurrent protecting signal (PR_OC), and the overvoltage threshold voltage (VTH_OV) is replaced with the overcurrent threshold voltage (VTH_OC).

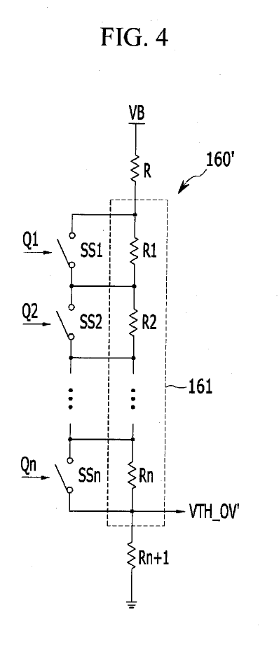

Another exemplary embodiment of the present invention will now be described with reference to FIG. 4

In the above-described exemplary embodiment, the threshold voltage generator 160 includes a plurality of sink current sources and a current mirror circuit. The threshold voltage generator 160′ according to another exemplary embodiment of the present invention includes a plurality of resistors and a plurality of switches.

FIG. 4 shows a threshold voltage generator according to another exemplary embodiment of the present invention.

As shown in FIG. 4, the threshold voltage generator 160′ includes a resistor string 161 formed by connecting a plurality of resistors (R1-Rn) in series, a resistor R0 connected between the voltage source (VB) and the resistor string 161, a resistor Rn+1 connected between the ground and the resistor string 161, and a plurality of resistor switches (SS1-SSn).

The resistor R0 includes a first end connected to a voltage source (VB) and a second end connected to a first end of the resistor string 161, and the resistor Rn+1 includes a grounded first end and a second end connected to a second end of the resistor string 161.

A plurality of resistor switches (SS1-SSn) are connected in parallel with corresponding resistors among a plurality of resistors (R1-Rn) of the resistor string 161. The resistor switches (SS1-SSn) are switched according to a plurality of output signals (Q1-Qn) of the register 150 described in the previous exemplary embodiment. For example, the resistor switch SS1 is turned on by the high-level output signal Q1 and is turned off by the low-level output signal Q1.

The overvoltage threshold voltage (VTH_OV′) represents a node voltage of the resistor Rn+1 and the resistor string 161, and depends on the number of turned-on resistor switches from among the resistor switches (SS1-SSn). For example, when the number of turned-on resistor switches from among the resistor switches (SS1-SSn) is increased, a weight of the resistor Rn+1 for the resistor string 161 is increased and the overvoltage threshold voltage (VTH_OV′) is increased.

In this instance, when the generated overvoltage threshold voltage (VTH_OV′) is less than a desired condition, the set resistor R1 is reduced, and in another case, the set resistor R1 is increased.

When the set resistor R1 is reduced, the set current (ISET) for maintaining the voltage VP1 of the pin 1 at the set reference voltage VR1 is increased and the set voltage (VSET) is also increased. The number of high-level output signals from among the plurality of output signals (Q1-Qn) is increased and the number of the turned-on resistor switches from among the resistor switches (SS1-SSn) is increased. The weight of the resistor Rn+1 for the resistor string 161 is increased and the overvoltage threshold voltage (VTH_OV′) is increased.

The overvoltage threshold voltage (VTH_OV′) is shown in FIG. 4 as a node voltage that is generated when the resistor string 161 meets the resistor Rn+1, and the exemplary embodiment of the present invention is not limited thereto. That is, the voltage generated when the resistor R0 meets the resistor string 161 can be the overvoltage threshold voltage (VTH_OV′). In the above-noted condition, when the generated overvoltage threshold voltage (VTH_OV′) is less than the desired condition, the set resistor R1 is increased, and in another case, the set resistor R1 is reduced.

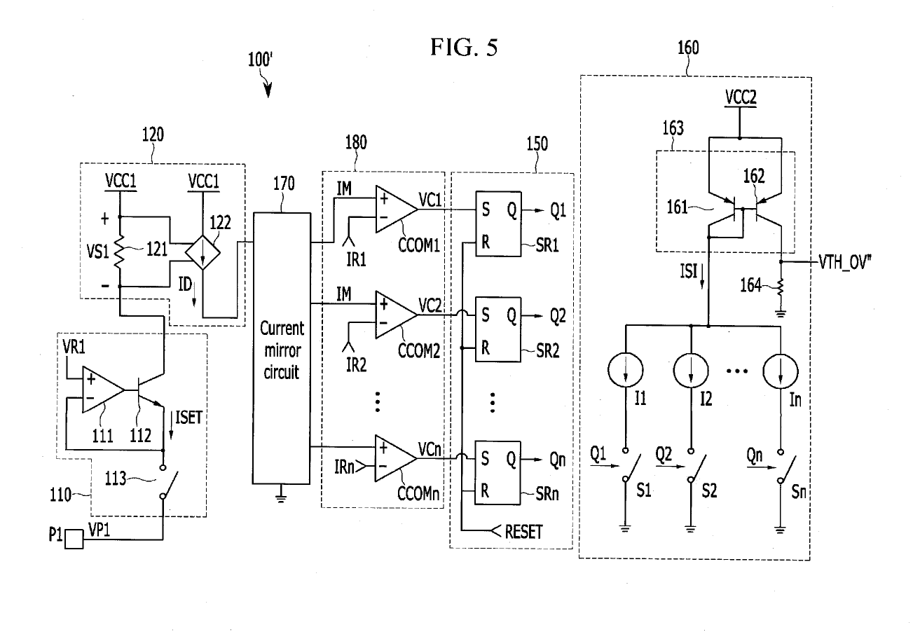

An OV threshold voltage setter 100′ according to the other exemplary embodiment of the present invention will now be described with reference to FIG. 5.

FIG. 5 shows an OV threshold voltage setter according to the other exemplary embodiment of the present invention.

In the above-described exemplary embodiments, the comparator 150 includes a plurality of voltage comparators (VCOM1-VCOMn) for comparing the set voltage (VSET) passing through the RC filter 140 and a plurality of reference voltages (VT1-VTn). The comparator 180 according to the other exemplary embodiment of the present invention includes a current comparator (CCOM1-CCOMn) other than the voltage comparator.

The OV threshold voltage setter 100 includes a second current mirror circuit 170 for mirroring the dependent current (ID) output by the voltage-current converter 120 and transmitting the same to the comparator 180, other than the RC filter for generating the set voltage (VSET).

The second current mirror circuit 170 mirrors the dependent current (ID) according to a predetermined mirror ratio and generates a plurality of mirror currents (IM). For ease of description, the mirror ratio according to the exemplary embodiment of the present invention is assumed to be 1:1. The mirror currents (IM) have the same level as the dependent current (ID).

The comparator 180 compares a plurality of reference currents (IR1-IRn) and the mirror currents (IM), and generates a plurality of current comparing signals (VIC1-VICn) according to the comparison result. The comparator 180 includes a plurality of current comparators (CCOM1-CCOMn).

The current comparators (CCOM1-CCOMn) respectively include an inverting terminal (−) for receiving a corresponding reference current from among a plurality of reference currents (IR1-IRn) and a non-inverting terminal (+) for receiving a mirror current (IM), and generate a plurality of current comparing signals (VIC1-VICn) according to comparison results.

The current comparators (CCOM1-CCOMn) respectively output a high-level signal when the input of the non-inverting terminal (+) is greater than the input of the inverting terminal (−), and they output a low-level signal. Therefore, the number of high-level current comparing signals from among a plurality of current comparing signals (VIC1-VICn) depends on the mirror current (IM).

For example, as the mirror current (IM) becomes greater, the number of high-level current comparing signals from among a plurality of current comparing signals (VIC1-VICn) is increased.

The current comparing signals (VIC1-VICn) are respectively transmitted to the set terminal (S) of the corresponding SR latch from among a plurality of SR latches (SR1-SRn) included in the register 150.

The SR latches (SR1-SRn) of the register 150 respectively include a set terminal (S) for receiving a corresponding current comparing signal from among a plurality of current comparing signals (VIC1-VICn) and a reset terminal (R) for receiving the reset signal (RESET), and it generates a high-level output when the input of the set terminal (S) is high-level, it maintains the current output when the input of the set terminal (S) is low-level, and it resets the output when the input of the reset terminal (R) is high-level.

The threshold voltage generator 160 generates an overvoltage threshold voltage (VTH_OV″) according to the sink current controllable by the output signals (Q1-Qn) of the register 150.

The configuration of the current generator 110 and the voltage-current converter 120 provided in the former part of the current mirror circuit 170 corresponds to that of the above-described exemplary embodiment, and it will not be described.

Accordingly, the OV threshold voltage setter 100′ according to the other exemplary embodiment of the present invention uses the current comparator to set the overvoltage threshold voltage (VTH_OV″).

Further, the OV threshold voltage setter 100″ according to the other exemplary embodiment of the present invention can include a threshold voltage generator 160′ other than the threshold voltage generator 160 described in the above-noted exemplary embodiment.

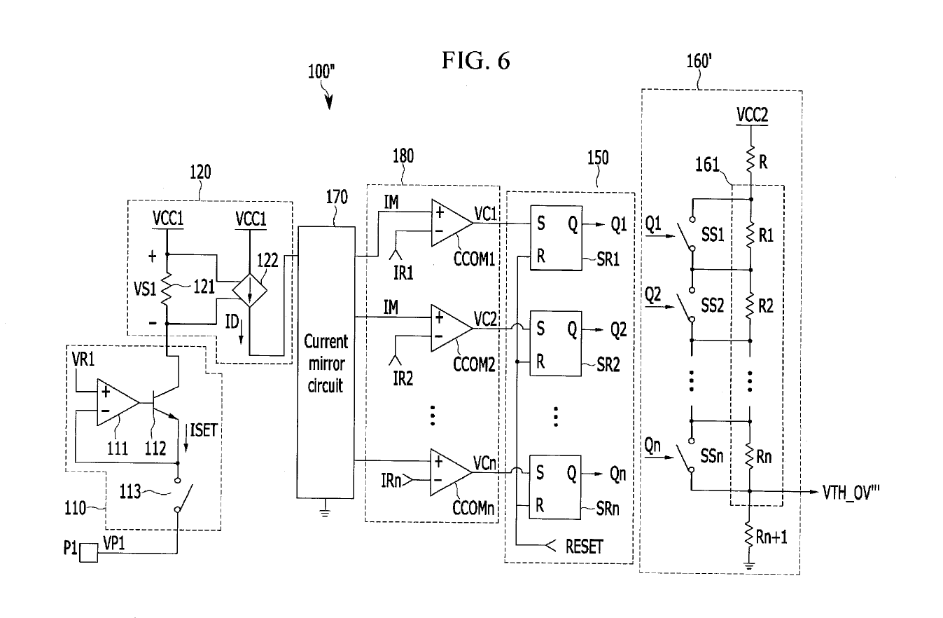

FIG. 6 shows an OV threshold voltage setter according to the other exemplary embodiment of the present invention.

As shown in FIG. 6, the OV threshold voltage setter 100″ uses the threshold voltage generator 160′ to generate an overvoltage threshold voltage (VTH_OV″′).

The current comparing signals (VIC1-VICn) are respectively transmitted to the set terminal (S) of the corresponding SR latch from among a plurality of SR latches (SR1-SRn) included in the register 150.

The SR latches (SR1-SRn) of the register 150 respectively include a set terminal (S) for receiving a corresponding current comparing signal from among a plurality of current comparing signals (VIC1-VICn) and a reset terminal (R) for receiving the reset signal (RESET), generate a high-level output when the input of the set terminal (S) is high-level, maintain the current output when the input of the set terminal (S) is low-level, and reset the output when the input of the reset terminal (R) is high-level.

A plurality of resistor switches (SS1-SSn) of the threshold voltage generator 160′ are connected in parallel to the corresponding resistor from among the resistors (R1-Rn) of the resistor string 161. The resistor switches (SS1-SSn) are switched according to the output signals (Q1-Qn) of the register 150 described in the previous exemplary embodiment.

The overvoltage threshold voltage (VTH_OV″′) represents a node voltage of the resistor Rn+1 and the resistor string 161, and follows the number of turned-on resistor switches from among the resistor switches (SS1-SSn)

The setting circuit according to the exemplary embodiments of the present invention includes a pin through which the set resistor for setting the reference voltage and the set capacitor for setting the delay time are connected with each other. Also, the setting circuit maintains the reference voltage and the delay time without an additional memory.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A setting circuit connected to a set resistor and a set capacitor through a pin, comprising:
a threshold voltage setter for setting a threshold voltage according to a resistance of the set resistor; and
a delay setter for determining a count frequency according to a capacitance of the set capacitor and setting a delay time according to the count frequency.

2. The setting circuit of claim 1, wherein the threshold voltage setter supplies a set current to the set resistor and uses a dependent current following the set current to set the threshold voltage.

3. The setting circuit of claim 2, wherein the threshold voltage setter sums currents of a plurality of selected sink current sources selected from among a plurality of sink current sources to generate a summed sink current according to a result of comparing a set voltage generated from the dependent current and a plurality of reference voltages, and sets the threshold voltage according to the summed sink current.

4. The setting circuit of claim 3, wherein the threshold voltage setter includes:
a plurality of voltage comparators including a first input terminal for receiving the set voltage and a second input terminal for receiving a corresponding reference voltage from among the plurality of reference voltages;
a plurality of SR latches for maintaining outputs of the voltage comparators, and generating a plurality of output signals according to the outputs of the voltage comparators; and
a threshold voltage generator that selects the plurality of selected sink current sources according to the plurality of output signals of the SR latches and for generating the summed sink current.

5. The setting circuit of claim 4, wherein
the threshold voltage generator includes:
a plurality of sink switches connected between first ends of the sink current sources and a ground;
a first current mirror circuit including an input terminal connected to second ends of the sink current sources, mirroring the summed sink current flowing through the input terminal to generate a mirrored summed sink current, and outputting the mirrored summed sink current to an output terminal; and
an output resistor connected to the output terminal of the first current mirror circuit, wherein
the sink switches are respectively switched according to a corresponding output signal from among the plurality of output signals of the plurality of SR latches, and the threshold voltage is generated at the output resistor.

6. The setting circuit of claim 2, wherein the threshold voltage setter generates a determined resistance by determining a resistance of a resistor string according to a result of comparing a set voltage generated from the dependent current and a plurality of reference voltages, and sets the threshold voltage according to the determined resistance.

7. The setting circuit of claim 6, wherein the threshold voltage setter includes:
a plurality of voltage comparators including a first input terminal for receiving the set voltage and a second input terminal for receiving a corresponding reference voltage from among the plurality of reference voltages;
a plurality of SR latches for maintaining outputs of the plurality of voltage comparators, and generating a plurality of output signals according to outputs of the respective voltage comparators; and
a threshold voltage generator for determining the resistance of the resistor string according to the plurality of output signals of the SR latches, and generating the threshold voltage according to the determined resistance.

8. The setting circuit of claim 7, wherein the threshold voltage setter includes:
a plurality of resistor switches, each of the resistor switches being connected in parallel to a corresponding resistor in a plurality of resistors that form the resistor string; and
a first resistor connected to a voltage source by way of the resistor string,
wherein the resistor switches are respectively switched according to a corresponding output signal from among the plurality of output signals of the SR latches, and the threshold voltage is generated between the first resistor and the voltage source.

9. The setting circuit of claim 2, wherein the threshold voltage setter generates a summed sink current by summing currents of a plurality of selected sink current sources selected from among a plurality of sink current sources according to a result of comparing the dependent current and a plurality of reference currents, and sets the threshold voltage according to the summed sink current.

10. The setting circuit of claim 9, wherein
the threshold voltage setter includes:
a second current mirror circuit for generating a mirror current by mirroring the dependent current;
a plurality of current comparators including a first input terminal for receiving the mirror current and a second input terminal for receiving a corresponding reference current from among the plurality of reference currents;
a plurality of SR latches for maintaining outputs of the current comparators, and generating a plurality of output signals according to the outputs of the current comparators; and
a threshold voltage generator that selects the plurality of selected sink current sources according to the plurality of output signals of the SR latches.

11. The setting circuit of claim 10, wherein the threshold voltage generator includes:
a plurality of sink switches connected between first ends of the sink current sources and a ground;
a first current mirror circuit including an input terminal connected to the second ends of the sink current sources, mirroring the summed sink current flowing through the input terminal to generate a mirrored summed sink current, and outputting the mirrored summed sink current to an output terminal; and
an output resistor connected to the output terminal of the first current mirror circuit,
wherein the sink switches are switched according to a corresponding output signal from among the plurality of output signals of the SR latches, and the threshold voltage is generated on the output resistor.

12. The setting circuit of claim 2, wherein the threshold voltage setter generates a determined resistance by determining a resistance of a resistor string according to a result of comparing the dependent current and a plurality of reference currents, and sets the threshold voltage according to the determined resistance.

13. The setting circuit of claim 12, wherein
the threshold voltage setter includes:
a second current mirror circuit for generating a mirror current by mirroring the dependent current;
a plurality of current comparators including a first input terminal for receiving the mirror current and a second input terminal for receiving a corresponding reference current from among the reference currents;
a plurality of SR latches for maintaining outputs of the current comparators, and generating a plurality of output signals according to the outputs of the current comparators; and
a threshold voltage generator for determining the resistance of the resistor string according to the plurality of output signals of the SR latches, and generating the threshold voltage according to the determined resistance.

14. The setting circuit of claim 13, wherein
the threshold voltage setter includes:
a plurality of resistor switches, each of the resistor switches being connected in parallel to a corresponding resistor in a plurality of resistors that form the resistor string; and
a first resistor connected to a voltage source by way of the resistor string,
wherein the resistor switches are switched according to a corresponding output signal from among the plurality of output signals of the SR latches, and the threshold voltage is generated between the first resistor and the voltage source.

15. The setting circuit of claim 3, wherein
the threshold voltage setter further includes:
an error amplifier for amplifying a difference between a set reference voltage and a voltage on the set resistor to generate an amplified voltage difference output; and
a transistor operable by the amplified voltage difference output,
wherein the set current flows through the transistor.

16. The setting circuit of claim 3, wherein
the threshold voltage setter further includes:
a voltage-current converter for generating the dependent current according to a sense voltage that is generated from the set current; and
an RC filter including a resistor through which the dependent current flows to generate the set voltage and a capacitor connected in parallel to the resistor.

17. The setting circuit of claim 1, wherein the delay setter charges the set capacitor to increase a voltage at the pin, discharges the set capacitor to reduce the voltage at the pin, and sets the delay time when a result of counting count pulses that are generated when the voltage at the pin is increased or reduced reaches a predetermined number of threshold times.

18. The setting circuit of claim 17, wherein the delay setter includes:
a charge and discharge controller for charging and discharging the set capacitor according to the count pulse;
a comparator comparing a first result generated by comparing the voltage at the pin and a predetermined high reference voltage and a second result generated by comparing the voltage at the pin and a predetermined low reference voltage;
an SR latch for controlling charging of the set capacitor according to the first result and controlling discharging of the set capacitor according to the second result;
an AND gate for generating the count pulses according to an output of the SR latch; and
a counter for counting a period of the count pulses, and generating a protection signal when the result of counting the count pulses reaches the predetermined number of threshold times.

19. The setting circuit of claim 18, wherein the charge and discharge controller includes:
a current source for generating a charge current; and
a charge and discharge control switch connected between the current source and the pin, and switched according to the count pulses.

20. The setting circuit of claim 1, wherein a period in which the threshold voltage setter is connected to the pin is not overlapped over a period in which the delay setter is connected to the pin.

21. A system for managing a battery having a plurality of cells, comprising:
a control circuit sensing cell voltages of the cells and a current flowing through the battery, generating a detection signal according to a result of comparing the cell voltages and a threshold voltage, and performing a protecting operation according to at least one protection signal; and
a setting circuit for setting the threshold voltage, setting a delay time from a time when the detection signal is generated to a time when the protecting operation is performed, and generating the at least one protection signal, wherein
the setting circuit comprises a threshold voltage setter for setting the threshold voltage according to a resistance of a set resistor that is connected to the setting circuit through a pin, and a delay setter for determining a count frequency according to a capacitance of a set capacitor that is connected to the setting circuit through the pin and for setting the delay time according to the count frequency.

22. The system of claim 21, wherein the threshold voltage is set during an initialization interval and a register writing interval of the battery management system, and the delay time is set when the detection signal is generated after the initialization interval and the register writing interval are finished.
